(19) United States
(12) Patent Application Publication
(10) Pub. No.: US 2025/0246433 A1
(43) Pub. Date: Jul. 31, 2025

(54) METHOD OF FORMING A WIDE BAND GAP SEMICONDUCTOR DEVICE

(71) Applicant: Infineon Technologies AG, Neubiberg (DE)

(72) Inventors: Thomas Aichinger, Faak am See (AT); Michael Hell, Erlangen (DE); Wolfgang Bergner, Klagenfurt am Wérthersee (AT)

(21) Appl. No.: 19/038,826

(22) Filed: Jan. 28, 2025

(30) Foreign Application Priority Data
Jan. 29, 2024 (DE) 102024102420.8

(51) Int. Cl. H01L 21/266; H01L 21/265; H10D 30/01

(52) U.S. Cl. CPC H01L 21/266; H01L 21/26586; H10D 30/0297

(57) ABSTRACT

A method of forming a wide band gap semiconductor device is proposed. The method includes forming a trench extending into a wide band gap semiconductor body from a first surface of the wide band gap semiconductor body. The method further includes forming a shielding region including introducing dopants of a first conductivity type into the wide band gap semiconductor body through at least one of a bottom side or a sidewall of the trench by ion implantation. Thereafter, the method further includes expanding the trench including an expansion process of forming a sacrificial oxide lining sidewalls and a bottom side of the trench by thermal oxidation and removing the sacrificial oxide.

### TECHNICAL FIELD

The present disclosure is related to a method forming a semiconductor device, in particular to a method of forming a semiconductor device including a wide band gap semiconductor body.

### BACKGROUND

Technology development of new generations of wide band gap semiconductor devices, e.g. insulated gate field effect transistors (IGFETs) such as metal oxide semiconductor field effect transistors (MOSFETs) or insulated gate bipolar transistors (IGBTs), aims at improving electrical device characteristics and reducing costs by shrinking device geometries. Although costs may be reduced by shrinking device geometries, a variety of tradeoffs and challenges have to be met when increasing device functionalities per unit area. For example, reducing the area-specific on-state resistance, RₒₙXA, may be challenging in view of process-related variations when arranging trenches relative to doped regions or doped regions relative to one another. Such process-related variations may be caused by process technology including different lithographic levels. For example, formation of contacts, e.g. contact plugs or vias, on mesa regions may become challenging when shrinking the width of the mesa for reducing the area-specific on-state resistance, RₒₙXA.

There is a need for improving formation methods of wide band gap semiconductor devices.

### SUMMARY

An example of the present disclosure relates to a method of forming a wide band gap semiconductor device. The method includes forming a trench extending into a wide band gap semiconductor body from a first surface of the wide band gap semiconductor body. The method further includes forming a shielding region including introducing dopants of a first conductivity type into the wide band gap semiconductor body through at least one of a bottom side or a sidewall of the trench by ion implantation. Thereafter, the method further includes expanding the trench including an expansion process of forming a sacrificial oxide lining sidewalls and a bottom side of the trench by thermal oxidation and removing the sacrificial oxide.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of forming wide band gap semiconductor devices and together with the description serve to explain principles of the embodiments. Further embodiments are described in the following detailed description and the claims.

FIG. 1 schematically and exemplarily illustrate process features of forming a wide band gap semiconductor device.

FIGS. 2A to 2C are cross-sectional views for illustrating exemplary process features of forming a wide band gap semiconductor device.

FIGS. 3A to 3H are schematic cross-sectional views for illustrating process features of forming a SiC semiconductor device including a channel region on one sidewall of a gate trench.

FIGS. 4A to 4G are schematic cross-sectional views for illustrating process features of forming a SiC semiconductor device including a channel region on opposite first and second sidewalls of a gate trench.

FIGS. 5A and 5B are schematic cross-sectional views for illustrating exemplary process features of forming a columnar region and a connection region.

FIGS. 6A to 6C are schematic cross-sectional views for illustrating exemplary process features of forming a current spread layer.

FIGS. 7A and 7B are schematic cross-sectional views for illustrating exemplary process features of forming a connection region.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts,-functions,-processes,-operations or-steps, respectively. Such sub acts may be included and part of the disclosure of this single act unless explicitly excluded.

A configuration example of a method of forming a wide band gap semiconductor device may include forming a trench extending into a wide band gap semiconductor body from a first surface of the wide band gap semiconductor body. The method may further include forming a shielding region including introducing dopants of a first conductivity type into the wide band gap semiconductor body through at least one of a bottom side or a sidewall of the trench by ion implantation. Thereafter, the method may further include expanding the trench including an expansion process of forming a sacrificial oxide lining sidewalls and a bottom side of the trench by thermal oxidation and removing the sacrificial oxide.

The wide band gap semiconductor device may be part of an integrated circuit or may be a discrete semiconductor device or a semiconductor module, for example. The wide band gap semiconductor device may be or may include an insulated gate field effect transistor (IGFET) such as a metal oxide semiconductor field effect transistor (MOSFET) or an insulated gate bipolar transistor (IGBT), for example. The wide band gap semiconductor device may be a vertical semiconductor device having a load current flow between the first surface and a second surface opposite to the first surface. The vertical power semiconductor device may be configured to conduct currents of more than 1 A, or more than 10 A, or more than 30 A, or more than 50 A, or more than 75 A, or even more than 100 A, and may be further configured to block voltages between load electrodes, e.g. between collector and emitter on an IGBT, or between drain and source of a MOSFET, in the range of several hundreds of up to several thousands of volts, e.g. 400 V, 650 V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The wide band gap semiconductor device may be based on a wide band gap semiconductor body from a crystalline wide band gap semiconductor material having a band gap larger than the band gap of silicon, i.e. larger than 1.12 eV. The wide band gap semiconductor material may have a hexagonal crystal lattice and may be silicon carbide (SIC), by way of example. For example, the semiconductor material may be 2H—SiC(SiC of the 2H polytype), 6H-SIC or 15R-SiC. According to an example, the semiconductor material is silicon carbide of the 4H polytype (4H-SiC). The semiconductor body may include or consist of a semiconductor substrate having none, one or more than one semiconductor layers, e.g. epitaxially grown layers, thereon. One of the semiconductor layers may be a doped semiconductor layer of a current spread layer, for example.

The first surface may be a front surface or a top surface of the wide band gap semiconductor body, and the wide band gap semiconductor body may further have a second surface that may be a back surface or a rear surface of the wide band gap semiconductor body, for example. The wide band gap semiconductor body may be attached to a lead frame via the second surface, for example. Over the first surface of the wide band gap semiconductor body, bond pads may be arranged and bond wires may be bonded on the bond pads, for example.

For example, the trench may be stripe-shaped and may define the dimensions of a trench gate structure formed in the trench.

For realizing a desired current carrying capacity, the wide band gap semiconductor device may be designed by a plurality of parallel-connected wide band gap semiconductor device cells. The parallel-connected wide band gap semiconductor device cells may, for example, be wide band gap semiconductor device cells formed in the shape of a strip or a strip segment. Of course, the wide band gap semiconductor device cells can also have any other shape, e.g. circular, elliptical, polygonal such as hexagonal or octahedral. The wide band gap semiconductor device cells may be arranged in the transistor cell area of the wide band gap semiconductor body. The transistor cell area may be an area where an emitter region of an IGBT (or a source region of a MOSFET) and a collector region of an IGBT (or a drain region of a MOSFET) are arranged opposite to one another along the vertical direction. In the transistor cell area, a load current may enter or exit the wide band gap semiconductor body of the semiconductor device, e.g. via contact plugs on the first surface of the wide band gap semiconductor body. The wide band gap semiconductor device may further include an edge termination area that may include a termination structure. In a blocking mode or in a reverse biased mode of the wide band gap semiconductor device, the blocking voltage between the transistor cell area and a field-free region laterally drops across the termination structure. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

The first mask pattern may be formed as a first hard mask pattern, e.g. an oxide hard mask pattern. The first mask pattern may be defined by a photolithography process, for example. Dimensions and arrangement of opening(s) in the first mask pattern may define a layout of trench(es) for forming the trench gate structure of the semiconductor device, for example. The trench(es) may be formed by an etch process, for example. Before forming the first mask pattern, the method may further include introducing dopants into the wide band gap semiconductor body, e.g. by ion implantation, for defining semiconductor layers in the wide band gap semiconductor body, e.g. a current spread layer and/or a body layer and/or a source layer.

The ion implantation of dopants for the shielding region may be based on non-tilted and/or tilted ion implantation(s). By varying the tilt angle, dopants may also be implanted into the wide band gap semiconductor body through a lower part of the sidewall of the trench, for example. Before carrying out ion implantation process(es) through the bottom side and/or sidewall of the trench, a screening dielectric, e.g. a screening oxide having a thickness of, for example, 20 nm to 200 nm, may be formed on the bottom side and/or sidewalls of the trench. This may allow for reducing or avoiding channeling effects and for absorbing ions that have undergone scattering at the trench sidewalls. The screening dielectric may also be formed of other materials than oxide, e.g. polycrystalline silicon, or silicon nitride, or aluminum oxide, for example.

The expansion process is initiated by forming the sacrificial oxide lining sidewalls and the bottom side of the trench by thermal oxidation. A lateral and vertical expansion of the trench may be precisely controlled by oxidation time, temperature and partial oxygen pressure, for example. Optionally, a hydrogen treatment may be carried out before formation of the sacrificial oxide.

The methods described herein may allow for a self-aligned arrangement of a shielding region with respect to a trench gate structure. Critical alignment parameters of the shielding region such as lateral distance to the trench gate structure sidewall or vertical extent from a bottom of the trench gate structure as well as a width of the trench gate structure may be well controlled by ion implantation parameters, e.g. energy, of the ion implantation process for the shielding region as well as oxidation parameters, e.g. temperature, time and oxygen pressure, of the sacrificial oxide. This may simplify shrinking the width of the mesa including the source/body regions for reducing the area-specific on-state resistance.

For example, the expansion process may be repeated several times. Thus, formation of the sacrificial oxide by thermal oxidation and removal of the sacrificial oxide may be repeated several times. A thickness of the subsequently formed sacrificial oxides may differ from one another or may be equal, e.g. by controlling thermal oxidation times for each sacrificial oxide. Repetition of the sacrificial oxide formation and removal may allow for counteracting thickness limitations of a single sacrificial oxide that may be caused by a decreasing oxide growth rate with increasing oxide thickness, for example.

For example, a width of the trench at a first horizontal reference level may be expanded by 10% to 80%. In other words, each sidewall of opposite sidewalls of the trench may be offset laterally outwards compared to the trench width before the expansion process by 5% to 40% of the original width of trench. The first horizontal reference level may have a same vertical distance to the first surface as to a bottom side of the trench before the expansion process. For example, widening of the trench may be in the range from one or several tens of nanometers to one or several hundreds of nanometers.

For example, forming the wide band gap semiconductor device may further include forming a trench gate dielectric in the trench after the expansion process. Between the expansion process and the trench gate dielectric or directly before the trench gate dielectric, one or more cleaning processes for surface conditioning may be carried out. Forming the trench gate dielectric may be part of forming a trench gate structure that may also include forming a trench gate electrode. The trench gate dielectric may be formed by or may include an oxidation process, e.g. thermal oxidation process and/or oxide deposition process. Other dielectric materials may be used in addition to or as an alternative to the oxide. For example, high-k materials may be used. For example, the trench gate dielectric layer may include a high-k dielectric layer including at least one of Al₂O₃, ZrO₂, HfO₂, AlN, alumosilicate AISiOx, silicon La- or Si-doped HfO₂, TiO₂, Y₂O₃, or Si₃N₄. For example, the trench gate dielectric may include at least a first dielectric sub-layer and a second dielectric sub-layer. The first dielectric sub-layer adjoining to a channel region may have a dielectric constant that is smaller than the dielectric constant of the high-k dielectric sub-layer, e.g. be equal to or larger than the dielectric constant of SiO₂. For example, the first dielectric layer may include at least one of SiO₂, AlN, or Si₃N₄, for example. The trench gate electrode may include one or more conductive material(s), e.g. metal, metal alloys, e.g. Cu, Au, AlCu, Ag, or alloys thereof, metal compounds, e.g. TiN, highly doped semiconductor material such as highly doped polycrystalline silicon. The one or more conductive materials may form a layer stack, for example. The trench gate electrode may be electrically connected to a gate pad via a gate interconnection structure such as a gate runner, for example. The gate pad/interconnection structure and, for example, a first load electrode pad, e.g. a source pad of a MOSFET or an emitter pad of an IGBT, may be part of a wiring area over the wide band gap semiconductor body. Forming the wiring area may include forming one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) and/or contact line(s) may be formed in openings of the interlayer dielectric structure to electrically connect parts, e.g. metal lines or contact areas, of different wiring levels to one another.

For example, the method may further include, before forming the trench, forming a first mask pattern over the first surface of the wide band gap semiconductor body. The first mask pattern may have an opening exposing a transistor cell area of the wide band gap semiconductor body. The method may further include forming a source layer including introducing dopants of a second conductivity type into the transistor cell area of the wide band gap semiconductor body through the first surface by ion implantation. The ion implantation may be a blanket ion implantation in the transistor cell area. In other words, the source layer may be formed in an overall area of the transistor cell area. The method may further include forming a body layer including introducing dopants of the first conductivity type into the transistor cell area of the wide band gap semiconductor body through the first surface by ion implantation. Similar to the source layer, the body layer may be formed by a blanket ion implantation in the transistor cell area. The method may further include forming a current spread layer including dopants of the second conductivity type. Similar as the source layer and the body layer, forming the current spread layer may include including introducing dopants of the second conductivity type into the transistor cell area of the wide band gap semiconductor body through the first surface by a blanket ion implantation in the transistor cell area. In addition to or as an alternative, at least a part of the current spread layer may also be formed by an epitaxial layer deposition process. The layer deposition process may be part of a layer deposition on a wide band gap semiconductor substrate. The layer deposition may form the uppermost portion of the wide band gap semiconductor body into which the mesa regions confined by gate trenches are formed. Doping of the current spread layer with dopants of the second conductivity type may be carried out in-situ or by blanket ion implantation after the epitaxial layer deposition process, for example. A bottom side of the current spread layer may be located below a bottom side of the trench. In other words, a bottom side of the current spread layer may have a larger vertical distance to the first surface than a bottom side of the trench.

For example, a bottom side of the shielding region may be positioned at a smaller vertical distance to the first surface than a bottom side of the current spread layer. Thereby, a pn junction may be defined between the shielding region and the current spread layer at least at the bottom of the shielding region.

For example, the method may further include, before forming the trench, forming a second mask pattern over the first surface of the wide band gap semiconductor body. The second mask pattern may have an opening exposing a part of the transistor cell area of the wide band gap semiconductor body. The method may further include forming a columnar region including introducing dopants of the first conductivity type through the opening at the first surface into the transistor cell area of the wide band gap semiconductor body by ion implantation. The columnar region may contribute to electrically connecting the shielding region to an electrode pad over the first surface, for example.

For example, a bottom side of the columnar region may be positioned between a bottom side of the body region and a bottom side of the current spread layer. In some examples, the bottom side of the columnar region may also be positioned between a bottom side of the body region and a bottom side of the trench, or between a bottom side of the source layer and a bottom side of the body layer.

For example, the method may further include, after forming the trench, forming a connection region including introducing dopants of the first conductivity type into the wide band gap semiconductor body through a sidewall of the trench by ion implantation. A bottom side of the connection region may be adjusted by a tilt angle of the ion implantation and by taking a thickness of an ion implantation mask into account. The connection region may provide an electric coupling between the shielding region and the columnar region.

For example, the dopants of the first conductivity type of the connection region may be further introduced into the wide band gap semiconductor body through a bottom side of the trench by ion implantation. For example, the dopants may be concurrently implanted through the bottom side and through the sidewall by adjusting the tilt angle of the ion implantation. As an alternative or in addition to implanting the dopants through the sidewall and, optionally, the bottom side, a further ion implantation process, e.g. non-tilted or having a smaller tilt angle, may be carried out to introduce the dopants through the bottom side of the trench.

For example, the method may further include forming a third mask pattern over the first surface of the wide band gap semiconductor body. The third mask pattern may have an opening exposing a trench gate portion of the transistor cell area of the wide band gap semiconductor body. The method may further include etching the trench into the wide band gap semiconductor body via the opening in the third mask pattern. The third mask pattern may function as an ion implantation mask for forming the shielding region.

For example, before etching the trench, a connection region may be formed by introducing dopants of the first conductivity type into the wide band gap semiconductor body through the opening in the third mask pattern by ion implantation, e.g. tilted ion implantation.

For example, removing the sacrificial oxide may include wet etching. The wet etching may be based on a hydrofluoric acid, HF, etch solution, for example.

For example, the method may further include, after forming the trench and before forming the shielding region, forming an auxiliary dielectric lining sidewalls and a bottom side of the trench. For example, the auxiliary dielectric may be an oxide and may be formed by thermal oxidation and/or deposition. The auxiliary dielectric may act as a screen dielectric at a bottom side and/or sidewall of the trench for the ion implantation process of the shielding region, for example. The auxiliary dielectric may also be formed of other materials than oxide, e.g. polycrystalline silicon, or silicon nitride, or aluminum oxide, for example.

For example, the method may further include, after forming the shielding region and before expanding the trench, removing the auxiliary oxide. The auxiliary region may be removed by wet etching. The wet etching may be based on a hydrofluoric acid, HF, etch solution, for example.

Details with respect to structure, or function, or technical benefit of features described above with respect to a wide band gap semiconductor device such as a FET, or IGBT likewise apply to the exemplary methods described further below. Processing the wide bandgap semiconductor body may comprise one or more optional additional features corresponding to one or more aspects mentioned in connection with the proposed concept or one or more examples described above or below.

Some of the above and below examples are described in connection with a silicon carbide substrate. Alternatively, a wide band gap semiconductor substrate, e.g. a wide band gap wafer, may be processed, e.g. comprising a wide band gap semiconductor material different from silicon carbide. The wide band gap semiconductor wafer may have a band gap larger than the band gap of silicon (1.12 eV). For example, the wide band gap semiconductor wafer may be a silicon carbide (SiC) wafer, or gallium arsenide (GaAs) wafer.

Functional and structural details described with respect to the examples above shall likewise apply to the exemplary embodiments illustrated in the figures and described further below. In the illustrated examples, n-channel FETs or IGBTs are illustrated. However, the examples described herein may also be applied to p-channel devices, e.g. p-channel MOSFETs or p-channel IGBTs.

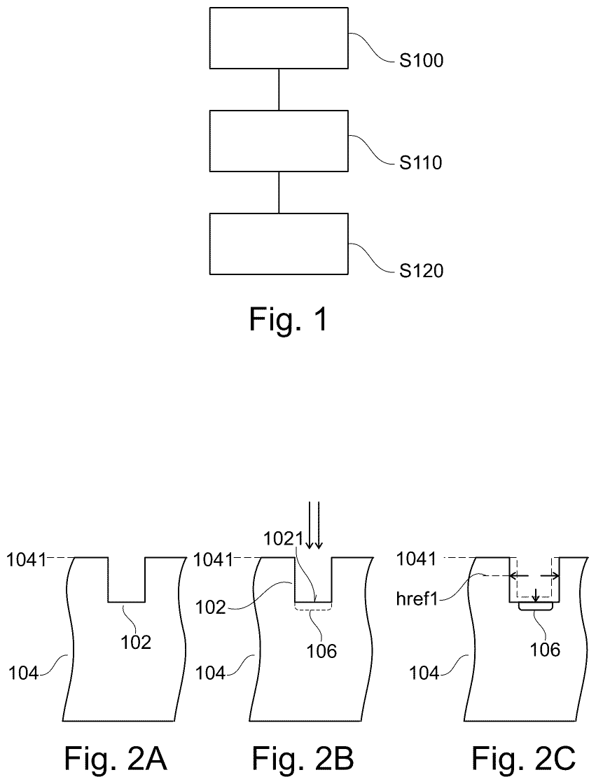

The process illustration of FIG. 1 refers to process features of forming a wide band gap semiconductor device. An exemplary and more detailed illustration of the process features of FIG. 1 are shown in the cross-sectional views of FIGS. 2A to 2C. The first conductivity type may be an n-type and the second conductivity type may be a p-type for an n-channel FET, for example. The first conductivity type may also be a p-type and the second conductivity type may be an n-type for a p-channel FET, for example.

Referring to process feature S100 of FIG. 1 and the exemplary cross-sectional view of FIG. 2A, process feature S100 includes forming a trench (e.g. the trench 102 in FIG. 2A), extending into a wide band gap semiconductor body (e.g. the wide band gap semiconductor body 104 in FIG. 2A) from a first surface (e.g. the first surface 1041 in FIG. 2A) of the wide band gap semiconductor body.

Referring to process feature S110 of FIG. 1 and the exemplary cross-sectional view of FIG. 2B, process feature S110 includes forming a shielding region (e.g. the shielding region 106 in FIG. 2B) including introducing dopants of a first conductivity type into the wide band gap semiconductor body through at least one of a bottom side or a sidewall of the trench by ion implantation.

Referring to process feature S120 of FIG. 1 and the exemplary cross-sectional view of FIG. 2C, process feature S120 includes expanding the trench including an expansion process of forming a sacrificial oxide lining sidewalls and a bottom side of the trench by thermal oxidation and removing the sacrificial oxide.

Referring to FIG. 2C, a width of the trench 102 at a first horizontal reference level href1 is expanded by 10% to 80%. The first horizontal reference level href1 has a same vertical distance to the first surface 1041 as to a bottom side 1021 of the trench 102 before the expansion process.

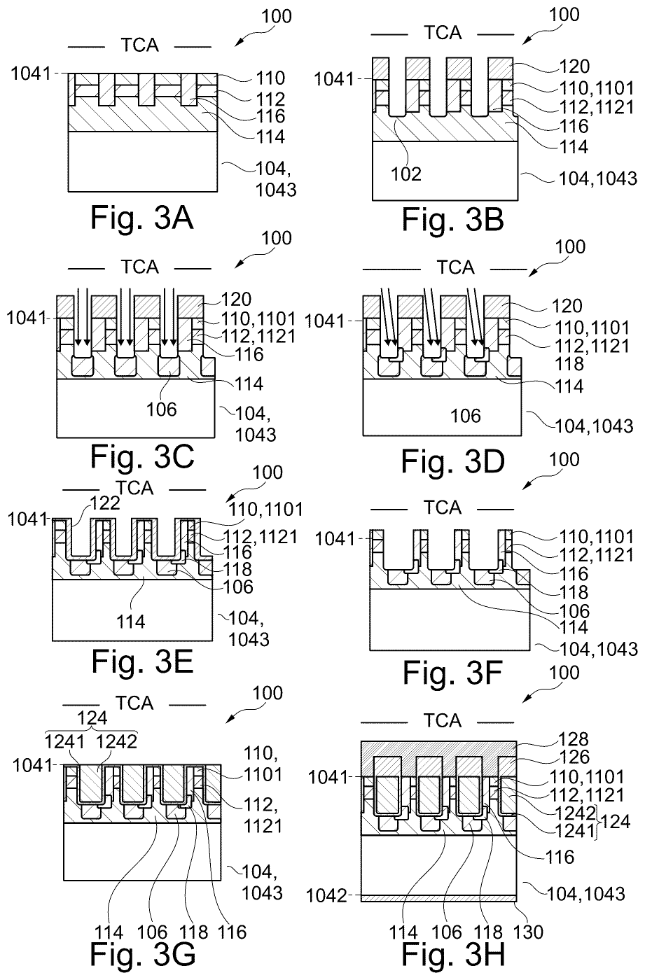

The schematic cross-sectional views of FIGS. 3A to 3H illustrate process features for forming a configuration example of a wide band gap semiconductor device 100 including a channel region on one of opposite sidewalls of a trench gate structure.

Referring to FIG. 3A, an n+-doped source layer 110 is formed in a transistor cell area TCA of a SiC semiconductor body 1043 by ion implantation of n-type dopants through the first surface 1041. The ion implantation process is blanket or unmasked with respect to the transistor cell area TCA. However, masked regions may be formed outside of the transistor cell area TCA (not illustrated in FIG. 3A). A p-doped body layer 112 is formed in the transistor cell area TCA of the SiC semiconductor body 1043 by ion implantation of p-type dopants through the first surface 1041 The ion implantation process is blanket or unmasked with respect to the transistor cell area TCA. An optional n-doped current spread layer 114 is formed in the transistor cell area TCA of the SiC semiconductor body 1043 by ion implantation of n-type dopants through the first surface 1041. The ion implantation process is blanket or unmasked with respect to the transistor cell area TCA. The ion implantation process of the n-doped current spread layer 114 may also be masked in order to have minimum overlap with the p-type shielding structure later (patterned current spread as illustrated in FIGS. 6A, 6B). This may be beneficial for avoiding leakage currents in blocking mode, for example. Instead, or in addition to implanting n-type dopants for forming the n-doped current spread layer 114, the current spread layer 114 may be formed by an epitaxial deposition process on a SiC base substrate when defining a semiconductor layer stack on the SiC base substrate. In this case, formation of the current spread layer 114 may be partly or fully completed before forming the source and/or body layers 110, 112.

A p-doped columnar region 116 is formed in the transistor cell area TCA of the SiC semiconductor body 1043 by a masked ion implantation process of p-type dopants through the first surface 1041 (ion implantation mask not illustrated in FIG. 3A. A bottom side of the p-doped columnar region 116 is positioned between a bottom side of the p-doped body region 112 and a bottom side of the n-doped current spread layer 114.

Referring to FIG. 3B, a mask pattern 120 is formed over the first surface 1041 of the SiC semiconductor body 1043. The mask pattern 120 has an opening exposing a trench gate portion of the transistor cell area TCA of the SiC semiconductor body 1043. A trench 102 is etched into the SiC semiconductor body 1043 via the opening in the mask pattern 120. Etching of the trench 102 patterns the source layer 110 into source regions 1101 and further patterns the body layer 112 into body regions 1121. On a first sidewall of the trench 102, a part of each of the source region 1101, the body region 1121 and the current spread layer 114 is exposed. On a second sidewall of the trench 102 opposite to the first sidewall, a part of each of the columnar region 116 and the current spread layer 114 is exposed.

Referring to FIG. 3C, p-type dopants are introduced into the SiC semiconductor body 1043 through at least one of a bottom side or a sidewall of the trench 102 by ion implantation, e.g. non-tilted or slightly tilted (tilt angles may also differ with respect to opposite sidewalls) ion implantation as illustrated in FIG. 3C for the non-tilted case. Thereby, a p-doped shielding region 106 is formed. For the ion implantation process of the p-type dopants for the shielding region 106, the mask pattern 120 may be used as an ion implantation mask.

Referring to FIG. 3D, p-type dopants are introduced into the SiC semiconductor body 1043 through a sidewall and/or bottom side of the trench 102 by ion implantation, e.g. tilted ion implantation as illustrated in FIG. 3D (tilt angle may be larger than in FIG. 3C, for example). Thereby, a p-doped connection region 118 is formed. For the ion implantation process of the p-type dopants for the connection region 118, the mask pattern 120 may be used as an ion implantation mask. The connection region 118 electrically connects the shielding region 106 and the columnar region 116. After forming the connection region 118, the mask pattern 120 is removed, e.g. by wet etching using, for example, an HF solution. High-temperature annealing (HTA) may follow.

Referring to FIG. 3E, an expansion process of the trench 102 is initiated by forming a sacrificial oxide 122 lining sidewalls and a bottom side of the trench 102 by thermal oxidation. Lateral and vertical expansion of the trench 102 can be precisely controlled by oxidation time, temperature and partial oxygen pressure, for example. Optionally, a hydrogen treatment may be carried out before or after formation of the sacrificial oxide 122.

Referring to FIG. 3F, the sacrificial oxide 122 is removed in the transistor cell area TCA, e.g. by wet etching using, for example, an HF solution. The expansion process of the trench 102 illustrated in FIGS. 3E and 3F may be repeated one or several times. The sacrificial oxide may be maintained in parts of the SiC semiconductor body 1043 outside of the transistor cell area TCA, e.g. in inactive chip areas by a resist mask protecting the sacrificial oxide 122 from the etch process.

Referring to FIG. 3G, a trench gate structure 124 is formed in the trench 102. Forming the trench gate structure 124 includes forming a trench gate dielectric 1241 in the trench 102, e.g. by thermal oxidation or deposition. Forming the trench gate structure 124 further includes forming a trench gate electrode 1242 on the trench gate dielectric 1241. Forming the trench gate structure 124 may further include a post oxidation anneal in a nitrogen containing atmosphere, for example. The trench gate electrode 1242 may include one or a stack of conductive materials, e.g. highly doped polycrystalline silicon.

Referring to FIG. 3H, an interlayer dielectric 126 is formed over the SiC semiconductor body 1043. A first load electrode 128, e.g. source or emitter electrode, is formed over the interlayer dielectric 126. The interlayer dielectric 126 electrically isolates the trench gate electrode 1242 from the first load electrode 128. Contact openings in the interlayer dielectric 126 enable an electric contact between the first load electrode 128 and the SiC semiconductor body 1043, e.g. the source and body regions 1101, 1121. A second load electrode 130, e.g. drain or collector electrode, is formed over a second surface 1042 of the SiC semiconductor body 1043. In some examples not illustrated in FIG. 3H, the interlayer dielectric 126 may be formed in an upper or top part of the trench 102.

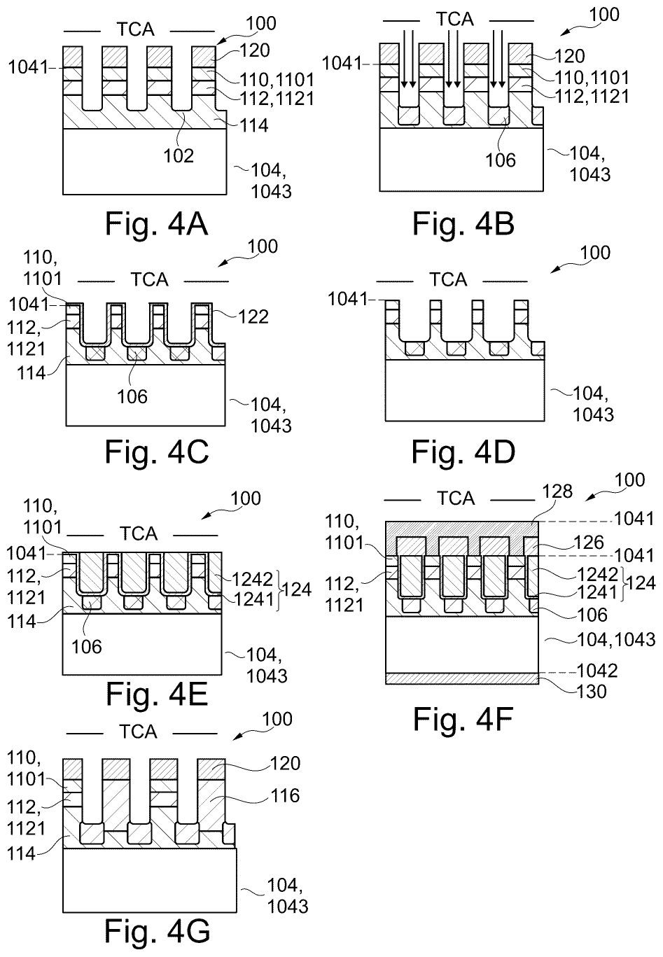

The schematic cross-sectional views of FIGS. 4A to 4G illustrate process features for forming a configuration example of a wide band gap semiconductor device 100 including a channel region on both of opposite sidewalls of a trench gate structure.

Referring to FIG. 4A, an n+-doped source layer 110 is formed in a transistor cell area TCA of a SiC semiconductor body 1043 by ion implantation of n-type dopants through the first surface 1041. The ion implantation process is blanket or unmasked with respect to the transistor cell area TCA. A p-doped body layer 112 is formed in the transistor cell area TCA of the SiC semiconductor body 1043 by ion implantation of p-type dopants through the first surface 1041. An n-doped current spread layer 114 is formed in the transistor cell area TCA of the SiC semiconductor body 1043 by ion implantation of n-type dopants through the first surface 1041. The ion implantation process is blanket or unmasked with respect to the transistor cell area TCA. Instead, or in addition to implanting n-type dopants for forming the n-doped current spread layer 114, the current spread layer 114 may be formed by an epitaxial deposition process on a SiC base substrate when defining the semiconductor layer stack of the SiC semiconductor body 1043. In this case, formation of the current spread layer 114 may be partly or fully completed before forming the source and/or body layers 110, 112. A mask pattern 120 is formed over the first surface 1041 of the SiC semiconductor body 1043. The mask pattern 120 has an opening exposing a trench gate portion in the transistor cell area TCA of the SiC semiconductor body 1043. A trench 102 is etched into the SiC semiconductor body 1043 via the opening in the mask pattern 120. Etching of the trench 102 patterns the source layer 110 into source regions 1101 and further patterns the body layer 112 into body regions 1121. On a first sidewall of the trench 102, a part of each of the source region 1101, the body region 1121 and the current spread layer 114 is exposed. Likewise, on a second sidewall of the trench 102 opposite to the first sidewall, a part of each of the source region 1101, the body region 1121 and the current spread layer 114 is exposed.

Referring to FIG. 4B, p-type dopants are introduced into the SiC semiconductor body 1043 through at least one of a bottom side or a sidewall of the trench 102 by ion implantation, e.g. non-tilted ion implantation as illustrated in FIG. 4B. Before carrying out the ion implantation, an optional auxiliary or screen dielectric, e.g. an oxide, may be formed and line sidewalls and a bottom side of the trench 102. The auxiliary dielectric may be formed by thermal oxidation and/or deposition, for example.

Thereby, a p-doped shielding region 106 is formed. For the ion implantation process of the p-type dopants for the shielding region 106, the mask pattern 120 may be used as an ion implantation mask.

Referring to FIG. 4C, an expansion process of the trench 102 is initiated by forming a sacrificial oxide 122 lining sidewalls and a bottom side of the trench 102 by thermal oxidation. Lateral and vertical expansion of the trench 102 can be precisely controlled by oxidation time, temperature and partial oxygen pressure, for example. Optionally, a hydrogen treatment may be carried out before or after formation of the sacrificial oxide 122.

Referring to FIG. 4D, the sacrificial oxide 122 is removed in the transistor cell area TCA, e.g. by wet etching using, for example, an HF solution. The expansion process of the trench 102 illustrated in FIGS. 4C and 4D may be repeated one or several times. The sacrificial oxide 122 may be maintained in parts of the SiC semiconductor body 1043 outside of the transistor cell area TCA, e.g. in inactive chip areas by a resist mask protecting the sacrificial oxide 122 from the etch process.

Referring to FIG. 4E, a trench gate structure 124 is formed in the trench 102. Forming the trench gate structure 124 includes forming a trench gate dielectric 1241 in the trench 102, e.g. by thermal oxidation. Forming the trench gate structure 124 further includes forming a trench gate electrode 1242 on the trench gate dielectric 1241. The trench gate electrode 1242 may include one or a stack of conductive materials, e.g. highly doped polycrystalline silicon. Forming the trench gate structure 124 may further include a post oxidation anneal in a nitrogen containing atmosphere, for example.

Referring to FIG. 4F, an interlayer dielectric 126 is formed over the SiC semiconductor body 1043. A first load electrode 128, e.g. source or emitter electrode, is formed over the interlayer dielectric 126. The interlayer dielectric 126 electrically isolates the trench gate electrode 1242 from the first load electrode 128. Contact openings in the interlayer dielectric 126 enable an electric contact between the first load electrode 128 and the SiC semiconductor body 1043, e.g. the source and body regions 1101, 1121. A second load electrode 130, e.g. drain or collector electrode, is formed over a second surface 1042 of the SiC semiconductor body 1043. In some examples not illustrated in FIG. 4F, the interlayer dielectric 126 may be formed in an upper or top part of the trench 102. For example, the interlayer dielectric may be completely formed in the trench 102.

The schematic cross-sectional view of FIG. 4G illustrates one example of connecting the p-doped shielding region 106 formed in the method illustrated in FIGS. 4A to 4F. For example, a p-doped columnar region 116 similar to the columnar region illustrated in FIG. 3A is formed at the process stage of forming the source layer 110, the body layer 112 and the current spread layer 114. The columnar region 116 is formed by a masked ion implantation process and extends deeper into the SiC semiconductor body 1043 than a bottom side of the trench 102.

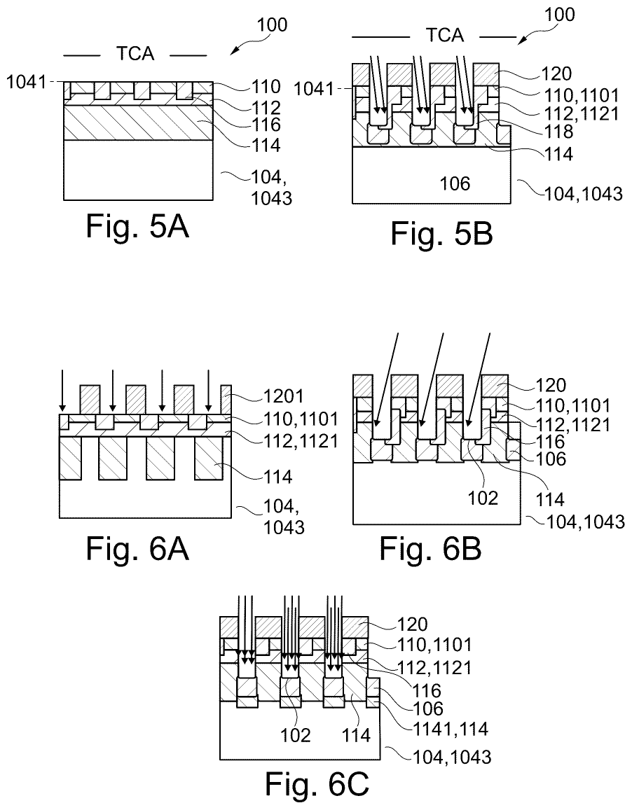

The schematic cross-sectional view of FIG. 5A illustrates another exemplary process feature that is based on FIG. 3A but differs from the example illustrated in FIG. 3A by a vertical extension of the p-doped columnar region 116. The p-doped columnar region 116 is formed in the transistor cell area TCA of the SiC semiconductor body 1043 by a masked ion implantation process of p-type dopants through the first surface 1041 (ion implantation mask not illustrated in FIG. 5A). A bottom side of the p-doped columnar region 116 in the example of FIG. 5A is positioned between a bottom side of the n+-doped source layer 110 and a bottom side of the p-doped body region 112. Process features similar to FIGS. 3B and 3C may follow.

Referring to FIG. 5B (that is based on FIG. 3D), p-type dopants are introduced into the SiC semiconductor body 1043 through a sidewall and/or bottom side of the trench 102 by ion implantation, e.g. tilted ion implantation as illustrated in FIG. 5D. Thereby, a p-doped connection region 118 is formed. For the ion implantation process of the p-type dopants for the connection region 118, the mask pattern 120 may be used as an ion implantation mask. The connection region 118 electrically connects the shielding region 106 and the columnar region 116. After forming the connection region 118, the mask pattern 120 is removed, e.g. by wet etching using, for example, an HF solution. High-temperature annealing (HTA) may follow. Further process features, e.g. as illustrated in FIGS. 3E to 3H, may follow.

The process features illustrated in FIGS. 3A, 4A and 5A are based on an ion implantation process of the n-doped current spread layer 114 that is blanket or unmasked with respect to the transistor cell area TCA. The following exemplary process features may likewise be used for forming the current spread layer 114. Referring to FIG. 6A, the ion implantation process of n-type dopants for forming the n-doped current spread layer 114 may also be masked. For example, a mask pattern 1201 that is inverse with respect to the mask pattern 120 illustrated in FIGS. 3B, 4B, 5B may be used. Referring to FIG. 6B, the n-type dopants for forming the n-doped current spread layer 114 may also be introduced through a sidewall of the trench 102 by a tilted ion implantation process. In addition to process features of forming the current spread layer 114 as illustrated in FIGS. 3A, 4A, 5A, 6A, 6B, a sub-region 1141 of the current spread layer 114 may be formed below the shielding region 106 by an ion implantation process through a bottom side of the trench 102, e.g., as shown in FIG. 6C.

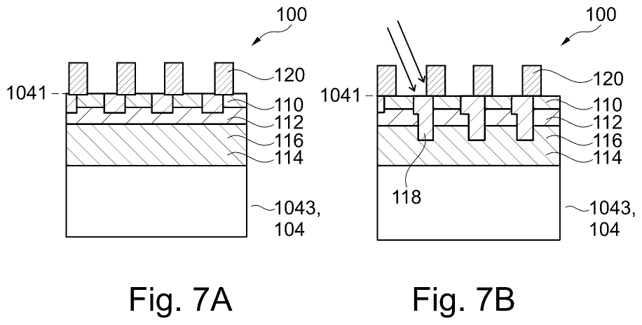

The schematic cross-sectional views of FIGS. 7A and 7B illustrate another configuration example of forming the connection region 118. The schematic cross-sectional view of FIG. 7A is based on FIG. 5A and illustrates the mask pattern 120 for forming the trench. Referring to the schematic cross-sectional view of FIG. 7B, a connection region 118 is formed by introducing dopants of the first conductivity type into the wide band gap semiconductor body 104 through the opening in the third mask pattern 120 by tilted ion implantation. Formation of the trench 102 by etching may follow. The configuration example illustrated in FIG. 7B differs from the example illustrated in FIG. 5B in that the connection region 118 is formed before etching the trench 102, for example.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming a wide band gap semiconductor device, the method comprising:
forming a trench extending into a wide band gap semiconductor body from a first surface of the wide band gap semiconductor body;
forming a shielding region including introducing dopants of a first conductivity type into the wide band gap semiconductor body through at least one of a bottom side or a sidewall of the trench by ion implantation; and
after forming the shieling region, expanding the trench including an expansion process of forming a sacrificial oxide lining sidewalls and a bottom side of the trench by thermal oxidation and removing the sacrificial oxide.

2. The method of claim 1, wherein the expansion process is repeated.

3. The method of claim 1, wherein a width of the trench at a first horizontal reference level is expanded by 10% to 80%, the first horizontal reference level having a same vertical distance to the first surface as to a bottom side of the trench before the expansion process.

4. The method of claim 1, further comprising:
after the expansion process, forming a trench gate dielectric in the trench.

5. The method of claim 1, further comprising, before forming the trench:
forming a first mask pattern over the first surface of the wide band gap semiconductor body, the first mask pattern having an opening exposing a transistor cell area of the wide band gap semiconductor body;
forming a source layer including introducing dopants of a second conductivity type into the transistor cell area through the first surface by ion implantation;
forming a body layer including introducing dopants of the first conductivity type into the transistor cell area through the first surface by ion implantation; and
forming a current spread layer including dopants of the second conductivity type.

6. The method of claim 5, wherein a bottom side of the shielding region is positioned at a smaller vertical distance to the first surface than a bottom side of the current spread layer.

7. The method of claim 6, further comprising, before forming the trench:
forming a second mask pattern over the first surface of the wide band gap semiconductor body, the second mask pattern having an opening exposing a part of the transistor cell area; and
forming a columnar region including introducing dopants of the first conductivity type through the opening at the first surface into the transistor cell area by ion implantation.

8. The method of claim 7, wherein a bottom side of the columnar region is positioned between a bottom side of the body layer and a bottom side of the current spread layer, or is positioned between a bottom side of the source layer and a bottom side of the body layer.

9. The method of claim 7, further comprising,
after forming the trench, forming a connection region including introducing dopants of the first conductivity type into the wide band gap semiconductor body through a sidewall of the trench by ion implantation.

10. The method of claim 9, wherein the dopants of the first conductivity type of the connection region are further introduced into the wide band gap semiconductor body through a bottom side of the trench by ion implantation.

11. The method of claim 5, further comprising:
forming a third mask pattern over the first surface of the wide band gap semiconductor body, the third mask pattern having an opening exposing a trench gate portion of the transistor cell area; and
etching the trench into the wide band gap semiconductor body via the opening in the third mask pattern; and
using the third mask pattern as an ion implantation mask to form the shielding region.

12. The method of claim 11, further comprising:
before etching the trench, forming a connection region including introducing dopants of the first conductivity type into the wide band gap semiconductor body through the opening in the third mask pattern by ion implantation.

13. The method of claim 1, wherein removing the sacrificial oxide includes wet etching.

14. The method of claim 1, further comprising:
after forming the trench and before forming the shielding region, forming an auxiliary dielectric lining sidewalls and a bottom side of the trench.

15. The method of claim 14, further comprising:
after forming the shielding region and before expanding the trench, removing the auxiliary dielectric.
